(19) United States
(12) Patent Application Publication
(10) Pub. No.: US 2026/0344047 A1
(43) Pub. Date: Oct. 29, 2026

(54) CIRCUIT ARRAY SUBSTRATE

(71) Applicant: AUO Corporation, Hsinchu City (TW)

(72) Inventors: Yi-Hsin Chou, Hsinchu City (TW); Kai-Teng Chiang, Hsinchu City (TW); Chun-Ru Huang, Hsinchu City (TW); Meng-Chiou Huang, Hsinchu City (TW); Che-Min Lin, Hsinchu City (TW); Chu-Kuan Yu, Hsinchu City (TW); FangMing Tsao, Hsinchu City (TW); Chun-Hsin Tai, Hsinchu City (TW)

(73) Assignee: AUO Corporation, Hsinchu City (TW)

(21) Appl. No.: 19/643,843

(22) Filed: Apr. 10, 2026

Related U.S. Application Data
(60) Provisional application No. 63/796,419, filed on Apr. 29, 2025.

(30) Foreign Application Priority Data
Sep. 24, 2025 (TW) 114136727

(51) Int. Cl. H10D 86/40; H10D 86/80; H10W 20/41

(52) U.S. Cl. CPC H10D 86/441; H10D 86/80; H10W 20/423

(57) ABSTRACT

A circuit array substrate includes a plurality of pixel units, wherein each of the pixel units includes a gate electrode layer, a semiconductor layer, a storage capacitor, and a first control capacitor. The gate electrode layer includes a first portion extending in a first direction and a second portion extending in a second direction, wherein the first direction is not parallel to the second direction. The semiconductor layer and the first portion of the gate electrode layer form a first transistor, and the semiconductor layer and the second portion of the gate electrode layer form a second transistor. A conductive plate of the storage capacitor is electrically connected to a first source/drain electrode of the first transistor. The semiconductor layer is a conductive plate of the first control capacitor.

### CROSS-REFERENCE TO RELATED APPLICATION

This application claims the priority benefit of U.S. provisional application serial no. 63/796,419, filed on Apr. 29, 2025, and Taiwan application serial no. 114136727, filed on Sep. 24, 2025. The entirety of each of the above-mentioned patent applications is hereby incorporated by reference herein and made a part of this specification.

### BACKGROUND OF THE INVENTION

### Field of the Invention

The invention relates to a circuit array substrate.

### Description of Related Art

After the scan signal is gated off, the storage capacitor (Cₛₜ) on the circuit array substrate may experience a voltage drop, resulting in the issue of leakage current.

### SUMMARY OF THE INVENTION

The invention provides a circuit array substrate that may reduce the probability of voltage drop in the storage capacitor therein.

According to an embodiment of the invention, a circuit array substrate is provided, including a plurality of pixel units, wherein each of the pixel units includes a gate electrode layer, a semiconductor layer, a storage capacitor, and a first control capacitor. The gate electrode layer includes a first portion extending in a first direction and a second portion extending in a second direction, wherein the first direction is not parallel to the second direction. The semiconductor layer and the first portion of the gate electrode layer form a first transistor, and the semiconductor layer and the second portion of the gate electrode layer form a second transistor. A conductive plate of the storage capacitor is electrically connected to a first source/drain electrode of the first transistor. The semiconductor layer is a conductive plate of the first control capacitor.

According to an embodiment of the invention, a circuit array substrate is provided, including a plurality of pixel units, wherein each of the pixel units includes a gate electrode layer, a semiconductor layer, a storage capacitor, and a first control capacitor. The gate electrode layer includes a first portion extending in a first direction and a second portion extending in a second direction, wherein the first direction is not parallel to the second direction. The semiconductor layer and the first portion of the gate electrode layer form a first transistor, and the semiconductor layer and the second portion of the gate electrode layer form a second transistor. A conductive plate of the storage capacitor is electrically connected to the first source/drain electrode of the first transistor. The semiconductor layer is a conductive plate of the first control capacitor. A ratio of the capacitance of the first control capacitor to a capacitance of the storage capacitor falls within a range of 1/65 to 1/55.

Based on the above, the circuit array substrate provided in an embodiment of the invention uses a control capacitor to reduce the probability of voltage drop in the storage capacitor, and the control capacitor does not affect the charging rate of the pixel unit to which it belongs.

To make the above features and advantages of the invention more apparent and understandable, specific embodiments are described below in conjunction with the accompanying drawings.

### BRIEF DESCRIPTION OF THE DRAWINGS

FIG. 1A shows a planar schematic view of a circuit array substrate according to the first embodiment of the invention, FIG. 1B shows a schematic cross-sectional view of a portion of the structure in FIGS. 1A, and 1C shows a circuit diagram of a portion of the structure in FIG. 1A.

FIGS. 2-9 respectively show schematic cross-sectional views of the circuit array substrate according to the second embodiment to the ninth embodiment of the invention.

### DESCRIPTION OF THE EMBODIMENTS

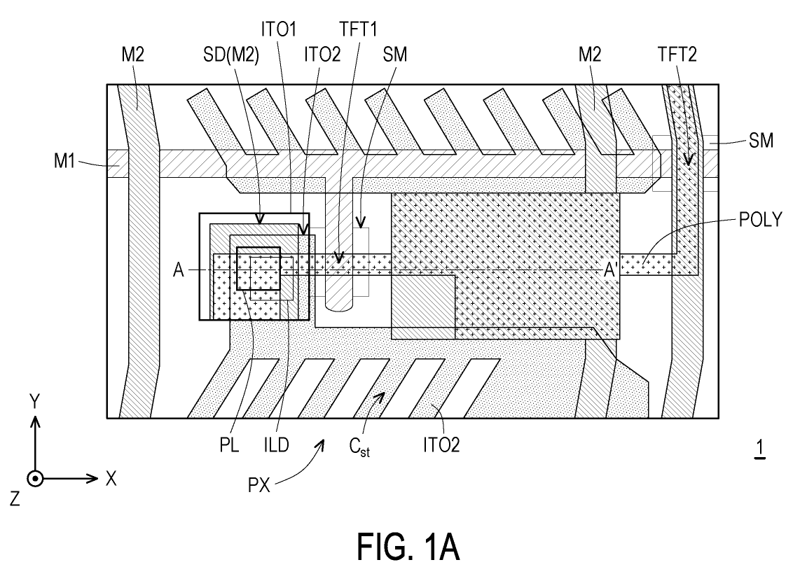

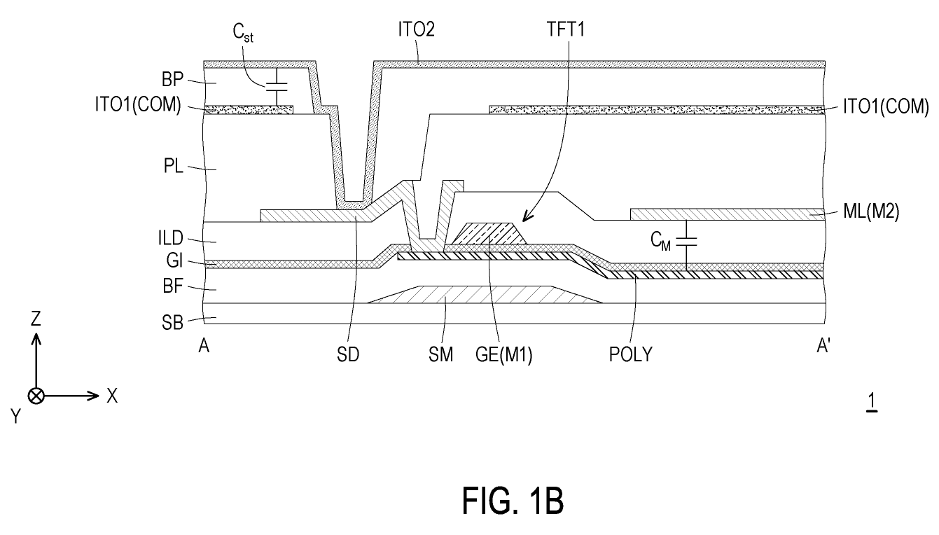

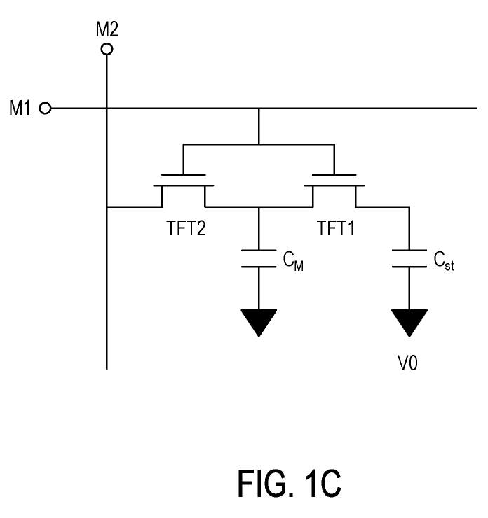

Referring to FIGS. 1A-1C, wherein FIG. 1A shows a planar schematic view of a circuit array substrate according to the first embodiment of the invention, FIG. 1B shows a schematic cross-sectional view of a portion of the structure in FIGS. 1A, and 1C shows a circuit diagram of a portion of the structure in FIG. 1A.

A circuit array substrate 1 includes a plurality of pixel units PX, wherein each of the pixel units PX includes a gate electrode layer M1, a data line layer M2, a semiconductor layer POLY, a storage capacitor Cₛₜ, and a control capacitor C_{M}.

The gate electrode layer M1 includes a first portion extending in the Y direction and a second portion extending in the X direction, wherein the X direction is perpendicular to the Y direction. However, the invention is not limited to the above vertical relationship. The extension direction of the first portion of the gate electrode layer M1 may be neither parallel to nor perpendicular to the extension direction of the second portion of the gate electrode layer M1.

The gate electrode layer M1 includes a gate electrode GE. The data line layer M2 includes a first source/drain electrode SD and a metal layer ML.

The semiconductor layer POLY and the first portion of the gate electrode layer M1 form a first transistor TFT1, and the semiconductor layer POLY and the second portion of the gate electrode layer M1 form a second transistor TFT2. The first transistor TFT1 is disposed on a substrate SB and includes the semiconductor layer POLY, the gate electrode GE, the first source/drain electrode SD, a second source/drain electrode (not shown), and a gate insulating layer GI located between the gate electrode GE and the semiconductor layer POLY.

The circuit array substrate 1 also has a shielding metal SM, a buffer layer BF located between the semiconductor layer POLY and the shielding metal SM, and an interlayer insulating layer ILD on the gate insulating layer GI disposed on the substrate SB, wherein the shielding metal SM is used to suppress dark current and may be formed by a single layer or multiple layers of any of molybdenum (Mo), copper (Cu), titanium (Ti), aluminum (Al), chromium (Cr), gold (Au), nickel (Ni), neodymium (Nd) or alloys thereof. The buffer layer BF may include, for example, at least one of silicon oxide (SiOx) or silicon nitride (SiNx). The interlayer insulating layer ILD may include, for example, at least one of silicon oxide (SiOx) or silicon nitride (SiNx).

Furthermore, the circuit array substrate 1 also has a planarization layer PL, a transparent conductive layer ITO1, an insulating layer BP, and a transparent conductive layer ITO2 sequentially disposed on the interlayer insulating layer ILD. The transparent conductive layer ITO1 is used as a common electrode layer COM and is subjected to a common voltage V0.

In the first embodiment, a conductive plate of the storage capacitor Cₛₜ is the transparent conductive layer ITO2, and the transparent conductive layer ITO2 is electrically connected to the first source/drain electrode SD of the first transistor TFT1, and serves as the pixel electrode of the pixel unit PX. Another conductive plate of the storage capacitor Cₛₜ is the transparent conductive layer ITO1 (the common electrode layer COM), and the transparent conductive layer ITO1 is subjected to the common voltage V0.

Moreover, a conductive plate of the control capacitor C_{M} is the semiconductor layer POLY. Another conductive plate of the control capacitor C_{M} is the metal layer ML (a portion of the data line layer M2).

It should be noted that, referring to both FIGS. 1B and 1C, the signal of the metal layer ML of the control capacitor C_{M} may be provided externally or may be the same as the potential of the common electrode layer COM. According to the scan signal provided to the gate electrode layer M1, the storage capacitor Cₛₜ and the control capacitor C_{M} may be charged simultaneously by the data voltage provided by the data line layer M2. When the scan signal is gated off, the voltage at the metal layer ML of the control capacitor C_{M} may reduce the probability of voltage drop in the storage capacitor Cₛₜ. Furthermore, in some preferred embodiments, the capacitance of the control capacitor C_{M} is configured to be 1/65 to 1/55 of the capacitance of the storage capacitor Cₛₜ, thereby ensuring that the increased control capacitor C_{M} does not affect the charging rate of the associated pixel unit. However, the invention is not limited thereto. In some embodiments, the ratio of the capacitance of the control capacitor CM to the capacitance of the storage capacitor Cst may fall within the range of 1/65 to 1/40, or be greater than 1/40.

To fully illustrate the various embodiments of the invention, other embodiments of the invention will be described below. It should be noted that the following embodiments adopt the reference numerals and some content of the above embodiments, wherein the same reference numerals are used to represent the same or similar elements, and the description of the same technical content is omitted. For explanations regarding the omitted portions, please refer to the above embodiments, which are not repeated in the following embodiments.

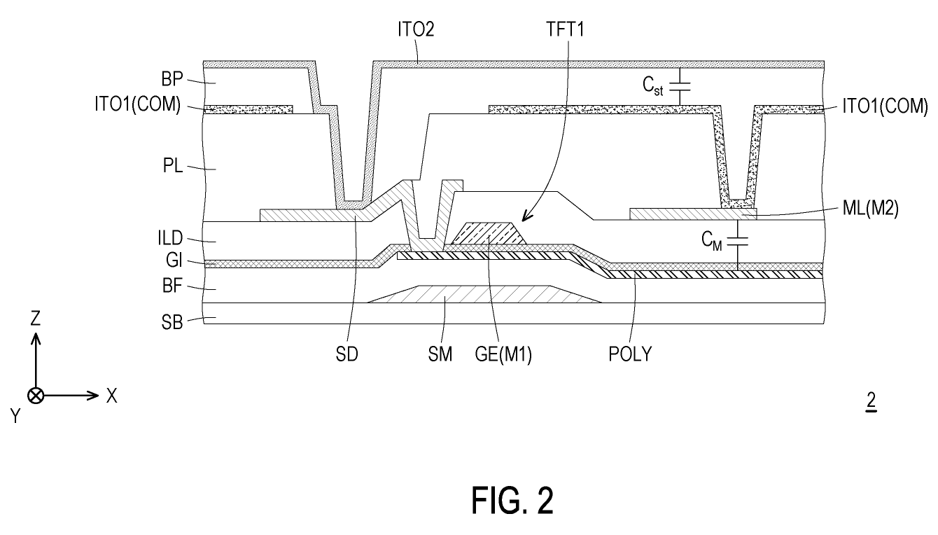

Referring to FIG. 2, a schematic cross-sectional view of a circuit array substrate 2 according to the second embodiment of the invention is shown.

In the circuit array substrate 2 of the second embodiment, a conductive plate of the control capacitor C_{M} is the semiconductor layer POLY, and another conductive plate thereof is the metal layer ML. The interlayer insulating layer ILD is used as the dielectric layer of the control capacitor C_{M}. The circuit array substrate 2 differs from the circuit array substrate 1 in that the metal layer ML is electrically connected to the transparent conductive layer ITO1 (the common electrode layer COM).

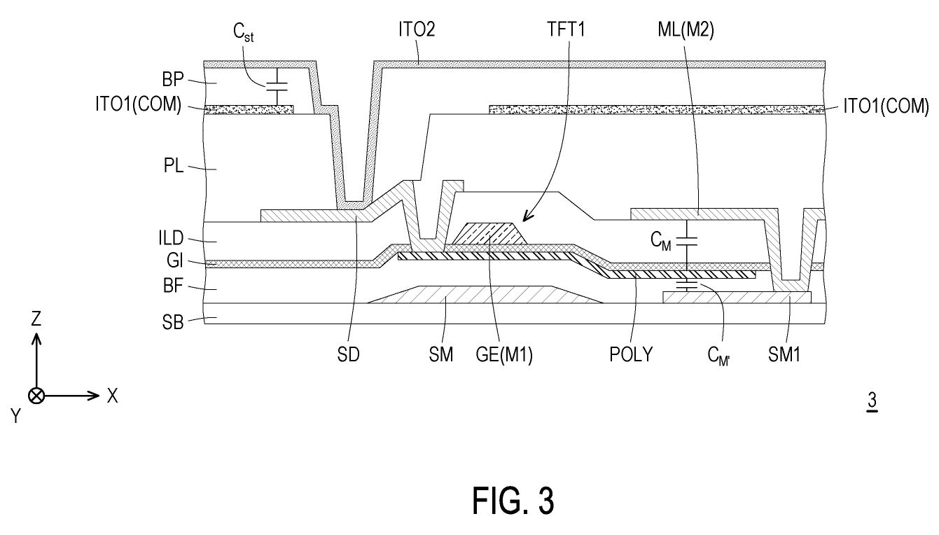

Referring to FIG. 3, a schematic cross-sectional view of a circuit array substrate 3 according to the third embodiment of the invention is shown.

In the circuit array substrate 3 of the third embodiment, a conductive plate of the control capacitor C_{M} is the semiconductor layer POLY, and another conductive plate thereof is the metal layer ML. The interlayer insulating layer ILD is used as the dielectric layer of the control capacitor C_{M}. The circuit array substrate 3 differs from the circuit array substrate 1 in that the circuit array substrate 3 also includes a shielding metal SM1 disposed on the same layer as the shielding metal SM and made of the same material, and the metal layer ML is electrically connected to the shielding metal SM1. Furthermore, the circuit array substrate 3 also includes a control capacitor C_{M’}, wherein the semiconductor layer POLY is a conductive plate of the control capacitor C_{M’}, and the shielding metal SM1 is another conductive plate of the control capacitor C_{M’}.

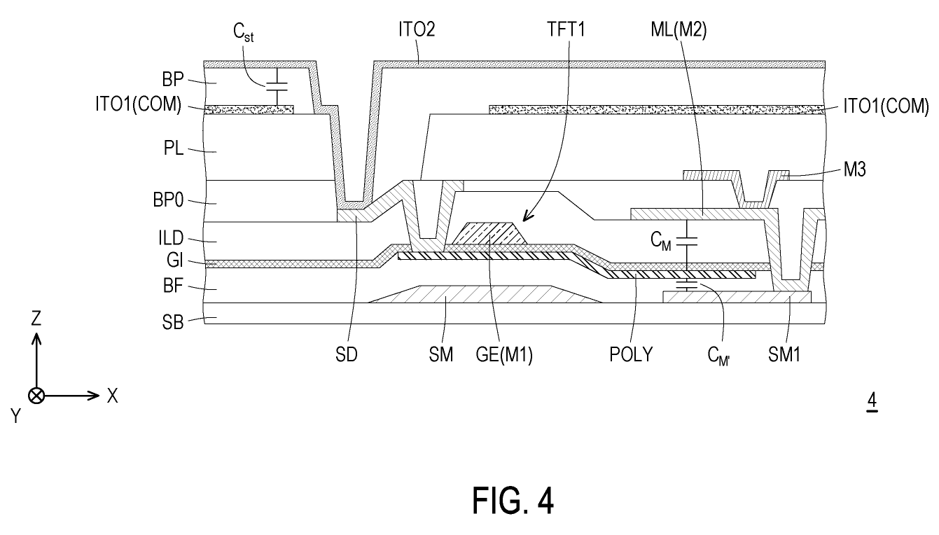

Referring to FIG. 4, a schematic cross-sectional view of a circuit array substrate 4 according to the fourth embodiment of the invention is shown.

In the circuit array substrate 4 of the fourth embodiment, a conductive plate of the control capacitor C_{M} is the semiconductor layer POLY, and another conductive plate thereof is the metal layer ML. The interlayer insulating layer ILD is used as the dielectric layer of the control capacitor C_{M}. The circuit array substrate 4 differs from the circuit array substrate 1 in that the circuit array substrate 4 also includes the shielding metal SM1 disposed on the same layer as the shielding metal SM and made of the same material, and an insulating layer BP0 between the planarization layer PL and the interlayer insulating layer ILD, and the metal layer ML electrically connected to the shielding metal SM1. Furthermore, the circuit array substrate 4 also includes a metal layer M3 and the control capacitor C_{M’}, wherein the semiconductor layer POLY is a conductive plate of the control capacitor C_{M’}, and the shielding metal SM1 is another conductive plate of the control capacitor C_{M’}. The buffer layer BF is used as the dielectric layer of the control capacitor C_{M’}. The metal layer M3 is electrically connected to the metal layer ML and may be used to transmit external signals, but is not limited thereto.

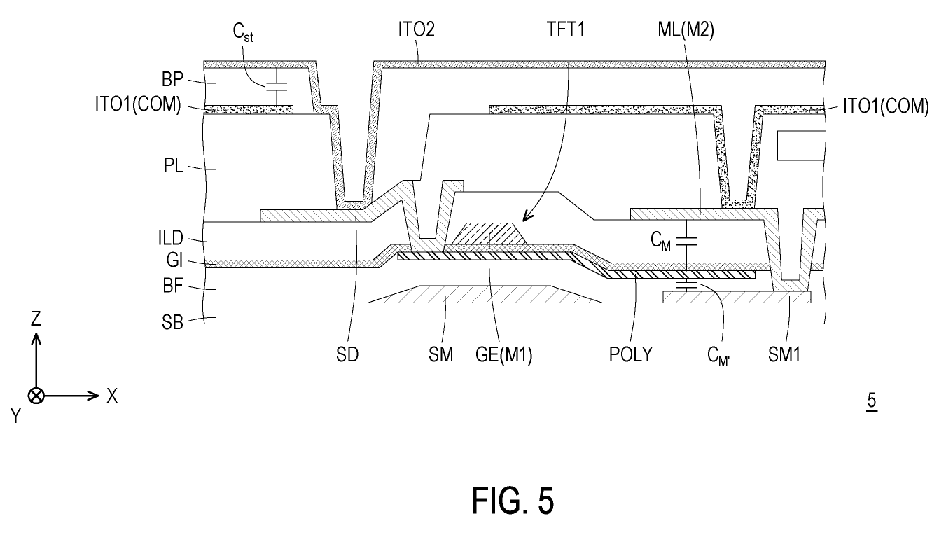

Referring to FIG. 5, a schematic cross-sectional view of a circuit array substrate 5 according to the fifth embodiment of the invention is shown.

In the circuit array substrate 5 of the fifth embodiment, a conductive plate of the control capacitor C_{M} is the semiconductor layer POLY, and another conductive plate thereof is the metal layer ML. The interlayer insulating layer ILD is used as the dielectric layer of the control capacitor C_{M}. The circuit array substrate 5 differs from the circuit array substrate 1 in that the circuit array substrate 5 also includes the shielding metal SM1 disposed on the same layer as the shielding metal SM and made of the same material, and the metal layer ML is electrically connected to the transparent conductive layer ITO1 (the common electrode layer COM) and the shielding metal SM1. Furthermore, the circuit array substrate 5 also includes the control capacitor C_{M’}, wherein the semiconductor layer POLY is a conductive plate of the control capacitor C_{M’}, and the shielding metal SM1 is another conductive plate of the control capacitor C_{M’}. The buffer layer BF is used as the dielectric layer of the control capacitor C_{M’}.

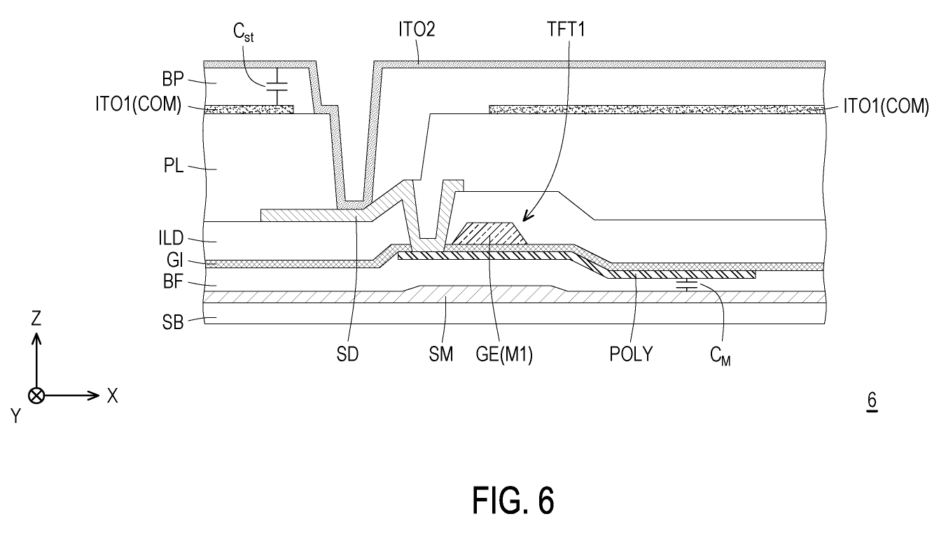

Referring to FIG. 6, a schematic cross-sectional view of a circuit array substrate 6 according to the sixth embodiment of the invention is shown.

The circuit array substrate 6 of the sixth embodiment differs from the circuit array substrate 1 in that a conductive plate of the control capacitor C_{M} is the semiconductor layer POLY, and another conductive plate thereof is the shielding metal SM, which may be used to transmit external signals, but is not limited thereto. The buffer layer BF is used as the dielectric layer of the control capacitor C_{M}.

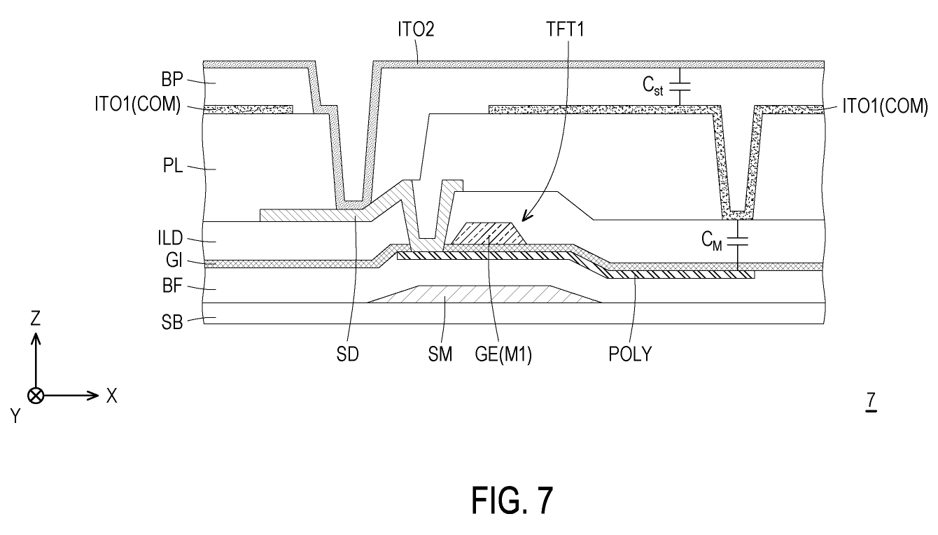

Referring to FIG. 7, a schematic cross-sectional view of a circuit array substrate 7 according to the seventh embodiment of the invention is shown.

In the circuit array substrate 7 of the seventh embodiment, a conductive plate of the control capacitor C_{M} is the semiconductor layer POLY, and another conductive plate thereof is the transparent conductive layer ITO1 (the common electrode layer COM). The interlayer insulating layer ILD is used as the dielectric layer of the control capacitor C_{M}.

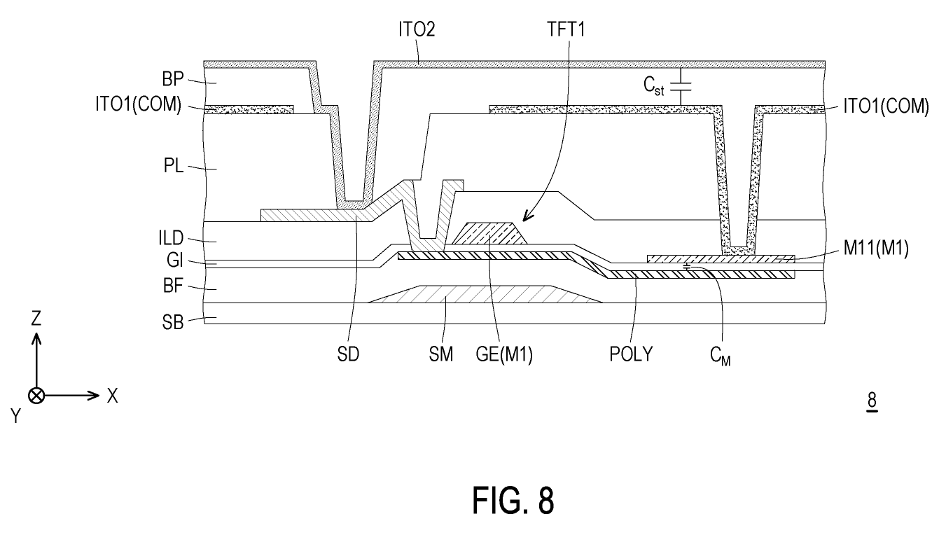

Referring to FIG. 8, a schematic cross-sectional view of a circuit array substrate 8 according to an eighth embodiment of the invention is shown.

In the circuit array substrate 8 of the eighth embodiment, the gate electrode layer M1 further includes a third portion M11, wherein the third portion M11 is located between the semiconductor layer POLY and the transparent conductive layer ITO1 (the common electrode layer COM), and is electrically connected to the transparent conductive layer ITO1 (the common electrode layer COM). A conductive plate of the control capacitor C_{M} is the semiconductor layer POLY, and another conductive plate thereof is the third portion M11 of the gate electrode layer M1. The gate insulation layer GI is used as the dielectric layer of the control capacitor C_{M}.

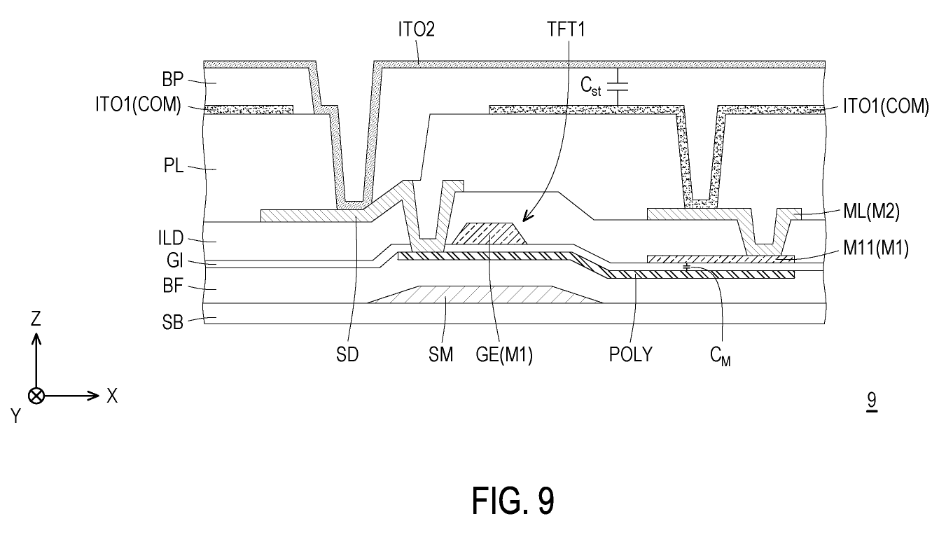

Referring to FIG. 9, a schematic cross-sectional view of a circuit array substrate 9 according to the ninth embodiment of the invention is shown.

The circuit array substrate 9 of the ninth embodiment differs from the circuit array substrate 1 in that the gate electrode layer M1 further includes a third portion M11, wherein the third portion M11 is located between the semiconductor layer POLY and the transparent conductive layer ITO1 (the common electrode layer COM), and is electrically connected to the transparent conductive layer ITO1 (the common electrode layer COM) via the metal layer ML. A conductive plate of the control capacitor C_{M} is the semiconductor layer POLY, and another conductive plate thereof is the third portion M11 of the gate electrode layer M1. The gate insulation layer GI is used as the dielectric layer of the control capacitor C_{M}.

In one or a plurality of the above embodiments, the interlayer insulating layer ILD is used as the dielectric layer of the control capacitor C_{M}, and the thickness thereof may be, for example, between 1000 Å and 9000 Å, between 750 Å and 9000 Å, between 500 Å and 10000 Å, between 450 Å and 10000 Å, between 400 Å and 12000 Å, between 400 Å and 10000 Å, between 400 Å and 9000 Å, between 400 Å and 6000 Å, between 400 Å and 1400 Å, and between 400 Å and 600 Å. Reducing the thickness of the dielectric layer ILD of the control capacitor C_{M} may decrease the area of the two conductive plates of the control capacitor C_{M}.

In one or a plurality of the above embodiments, the buffer layer BF is used as the dielectric layer of the control capacitor C_{M} or the dielectric layer of the control capacitor C_{M’}, and the thickness thereof may be, for example, between 1000 Å and 6000 Å, between 750 Å and 7000 Å, between 500 Å and 8000 Å, between 400 Å and 9000 Å, between 250 Å and 1000 Å, between 250 Å and 2000 Å, between 250 Å and 3000 Å, between 250 Å and 4000 Å, between 250 Å and 5000 Å, between 250 Å and 6000 Å, and between 250 Å and 10000 Å. Reducing the thickness of the dielectric layer BF of the control capacitor C_{M} or the control capacitor C_{M’} may decrease the area of the two conductive plates of the control capacitor C_{M} or the control capacitor C_{M’}.

In one or a plurality of the above embodiments, the gate insulating layer GI is used as the dielectric layer of the control capacitor C_{M}, and the thickness thereof may be, for example, between 500 Å and 2000 Å, between 400 Å and 2000 Å, between 375 Å and 2000 Å, between 350 Å and 2000 Å, between 300 Å and 400 Å, between 300 Å and 1000 Å, and between 300 Å and 2000 Å. By reducing the thickness of the dielectric layer GI of the control capacitor C_{M}, the area of the two conductive plates of the control capacitor C_{M} may be reduced.

Based on the above, the circuit array substrate provided in an embodiment of the invention utilizes a control capacitor to reduce the probability of voltage drop in the storage capacitor, and the control capacitor does not affect the charging rate of the pixel unit to which it belongs.

What is claimed is:

1. A circuit array substrate, comprising a plurality of pixel units, wherein each of the pixel units comprises:
a gate electrode layer comprising a first portion extending in a first direction and a second portion extending in a second direction, wherein the first direction is not parallel to the second direction;
a semiconductor layer, wherein the semiconductor layer and the first portion of the gate electrode layer form a first transistor, and the semiconductor layer and the second portion of the gate electrode layer form a second transistor;
a storage capacitor, wherein a conductive plate of the storage capacitor is electrically connected to a first source/drain electrode of the first transistor; and
a first control capacitor, wherein the semiconductor layer is a conductive plate of the first control capacitor.

2. The circuit array substrate of claim 1, further comprising a shielding metal, wherein the semiconductor layer is located between the shielding metal and the gate electrode layer, and another conductive plate of the first control capacitor is the shielding metal.

3. The circuit array substrate of claim 1, further comprising a data line layer, wherein the data line layer comprises the first source/drain electrode and a metal layer, and another conductive plate of the first control capacitor is the metal layer.

4. The circuit array substrate of claim 3, further comprising a common electrode layer, wherein the metal layer is electrically connected to the common electrode layer.

5. The circuit array substrate of claim 3, further comprising a shielding metal, wherein the semiconductor layer is located between the shielding metal and the gate electrode layer, and the metal layer is electrically connected to the shielding metal.

6. The circuit array substrate of claim 5, further comprising a second control capacitor, wherein the semiconductor layer is a conductive plate of the second control capacitor and the shielding metal is another conductive plate of the second control capacitor.

7. The circuit array substrate of claim 1, further comprising a common electrode layer, wherein another conductive plate of the first control capacitor is the common electrode layer.

8. The circuit array substrate of claim 1, further comprising a common electrode layer, wherein the gate electrode layer further comprises a third portion, the third portion of the gate electrode layer is located between the semiconductor layer and the common electrode layer, electrically connected to the common electrode layer, and forms another conductive plate of the first control capacitor.

9. The circuit array substrate of claim 8, further comprising a metal layer, wherein the metal layer and the first source/drain electrode are disposed in a same layer and materials thereof are same, and the metal layer is electrically connected to the third portion of the common electrode layer and the gate electrode layer.

10. The circuit array substrate of claim 4, wherein another conductive plate of the storage capacitor is the common electrode layer.

11. The circuit array substrate of claim 7, wherein another conductive plate of the storage capacitor is the common electrode layer.

12. The circuit array substrate of claim 8, wherein another conductive plate of the storage capacitor is the common electrode layer.

13. The circuit array substrate of claim 2, wherein the first control capacitor comprises a dielectric layer, and a thickness of the dielectric layer is between 250 Å and 6000 Å.

14. The circuit array substrate of claim 3, wherein the first control capacitor comprises a dielectric layer, and a thickness of the dielectric layer is between 400 Å and 9000 Å.

15. The circuit array substrate of claim 4, wherein the first control capacitor comprises a dielectric layer, and a thickness of the dielectric layer is between 400 Å and 9000 Å.

16. The circuit array substrate of claim 5, wherein the first control capacitor comprises a dielectric layer, and a thickness of the dielectric layer is between 400 Å and 9000 Å.

17. The circuit array substrate of claim 6, wherein the first control capacitor comprises a dielectric layer, and a thickness of the dielectric layer is between 400 Å and 9000 Å.

18. The circuit array substrate of claim 7, wherein the first control capacitor comprises a dielectric layer, and a thickness of the dielectric layer is between 400 Å and 9000 Å.

19. The circuit array substrate of claim 8, wherein the first control capacitor comprises a dielectric layer, and a thickness of the dielectric layer is between 300 Å and 2000 Å.

20. The circuit array substrate of claim 9, wherein the first control capacitor comprises a dielectric layer, and a thickness of the dielectric layer is between 300 Å and 2000 Å.

21. The circuit array substrate of claim 6, wherein the second control capacitor comprises a dielectric layer, and a thickness of the dielectric layer is between 250 Å and 6000 Å.

22. The circuit array substrate of claim 1, wherein a ratio of a capacitance of the first control capacitor to a capacitance of the storage capacitor falls within a range of 1/65 to 1/40.

23. A circuit array substrate, comprising a plurality of pixel units, wherein each of the pixel units comprises:
a gate electrode layer comprising a first portion extending in a first direction and a second portion extending in a second direction, wherein the first direction is not parallel to the second direction;
a semiconductor layer, wherein the semiconductor layer and the first portion of the gate electrode layer form a first transistor, and the semiconductor layer and the second portion of the gate electrode layer form a second transistor;
a storage capacitor, wherein a conductive plate of the storage capacitor is electrically connected to a first source/drain electrode of the first transistor; and
a first control capacitor, wherein the semiconductor layer is a conductive plate of the first control capacitor,
wherein a ratio of a capacitance of the first control capacitor to a capacitance of the storage capacitor falls within a range of 1/65 to 1/55.
